(19) United States
(12) Patent Application Publication
(10) Pub. No.: US 2015/0040388 A1
(43) Pub. Date: Feb. 12, 2015

(54) Application of Dielectric Layer and Circuit Traces on Heat Sink

(71) Applicant: APPLIED NANOTECH HOLDINGS, INC., Austin, TX (US)

(72) Inventors: Nan Jiang, Austin, TX (US); Zvi Yaniv, Austin, TX (US); James P. Novak, Austin, TX (US); Xueping Li, Austin, TX (US)

(73) Assignee: Applied Nanotech Holdings, Inc., Austin, TX (US)

(21) Appl. No.: 14/385,441

(22) PCT Filed: Mar. 20, 2013
(86) PCT No.: PCT/US2013/033109

§ 371 Date: Sep. 15, 2014

Related U.S. Application Data
(60) Provisional application No. 61/613,254, filed on Mar. 20, 2012.
(60) Provisional application No. 61/613,342, filed on Mar. 20, 2012.

(51) Int. Cl. H05K 3/00; H05K 3/06; F21K 99/00; H05K 3/44; H05K 3/46; H05K 3/12; H05K 3/34

(52) U.S. Cl. CPC H05K 3/0061; H05K 3/12; H05K 3/06; H05K 3/34; H05K 3/44; H05K 3/4655; F21K 9/90; H05K 2201/10106; F21Y 2101/02
USPC 29/832; 427/97.3; 156/280; 156/324.4

(57) ABSTRACT

A dielectric layer is directly applied onto the surface of a heat sink part. For example, the composition for making the dielectric layer may be made into a paste or ink and then printed as a paste or ink, or applied with some other equivalent method, such as a lamination technique. The electrical circuit traces are then printed in a similar fashion onto the dielectric layer in the required pattern for whatever circuitry is to be applied. That circuitry (e.g., circuit elements) is then attached to the electrical traces as needed for the particular application.

This application claims priority to U.S. Provisional Patent Applications Ser. Nos. 61/613,254 and 61/613,342, which are hereby Incorporated by reference herein.

### TECHNICAL FIELD

The present invention, relates in general to thermal management composite films, and in particular, to a thermal management composite film on which electrical circuits can be directly printed.

### BACKGROUND AND SUMMARY

A primary obstacle to readily implement energy-saving LED (“light emitting diode”) lighting systems in established commercial and municipal lighting networks lies in dealing with the heat that is generated by high-power LEDs, which are required to produce sufficient light output needed in commercial luminaries. State of the art LEDs can consume in excess of 10 watts each, and even at the efficiency levels of today's LEDs, the majority of that power is being converted to heat as a byproduct of the light generated in the semiconductor junction of the device.

This heat is internally generated in the structure of the LED chip; so, unlike a light bulb that radiates its heat; this heat needs to be mechanically conducted away from the LED junction as efficiently as possible to maintain proper operation of the LED. Rises in junction, temperature in the LED result in color-shifted, reduced-light output, and ultimately reduced life of the LED. Dealing with the heal and keeping the cost down for a given design is the task of every LED lighting developer.

Approaches to thermal management incorporate various .materials and architectures aimed at reducing the thermal resistance between the LED junction and the ambient environment This takes the form of 1) reducing the number of thermally resistant, layers between the LED junction and the environment, 2) reducing the thermal resistance of said layers, and 3) using electromechanical systems to facilitate the movement of heat into the environment.

Power LEDs are typically soldered on a printed circuit board to provide the electrical, connections. This circuit board is typically made by laminating the dielectric layer and Cu (copper) circuit traces on Al (aluminum) or Cu substrates, and then the circuit boards are mechanically fastened, to some secondary thermal path material, such as heat sink parts. In other words, the circuit board for electrically operating the LEDs is separately manufactured and then fastened (e.g., with screws or bolts) to a heat sink part. Of course, a significant problem with such an arrangement is that heat is not as efficiently transferred from the LEDs to the circuit boards to the heat sink parts.

Embodiments of the present invention eliminate the need for an interface circuit board and place the circuit directly on top of the heal sink surface.

Integrated thermal, management substrates are led by metal, core printed circuit boards (“MCPCBs”). These have a typical structure where a very thin layer of FR4 circuit board material, is bonded to the front side of an aluminum backing substrate. High performance MCPCBs will incorporate metal Savers with, higher thermal conductivity, such as capper, to increase the overall heat transfer of the board. The metal layer in the substrate increases the heat loss through the substrate by adding a material layer with high thermal conductivity that increases heat loss by conduction.

The backing of an MCPCB substrate will have a thickness that is near the common circuit board thickness of 1, 1.5, or 2 mm. Some examples may have additional thickness. A copper conduction layer is typically bonded to the top of the FR4 and patterned with the desired electrical circuit pattern. The individual circuit components are soldered onto the electrical circuit pattern to create the functional circuit. The aluminum backplane bonded to the FR4 circuit material has significantly higher thermal conductivity than a full FR4 circuit board. This allows for greater heat dissipation. However, these boards must still be interlaced with some type of secondary cooling system such as a heat sink structure.

There are multiple types of heat sink structures than can be used, for power electronics applications such as LEDs. The most common is a tinned heat sink that contains a flat section suitable for circuit board mounting on one face and a high surface are a finned structure on additional laces that help with, radiative heat loss to the surrounding atmosphere. Finned heat sinks are most commonly made from aluminum or copper and can be stamped, cast, machined, or extruded, or combinations thereof.

When the MCPCB is mounted to a heat sink, there are multiple interfaces incorporated in the structure that contribute to poor thermal transfer between the layers. From the electrical component there is an attachment interface between the electrical package and the substrate circuit. This attachment is most commonly a direct solder attachment. The solder layer typically has a thermal conductivity of 30-70 W/mK. Lead free solders typically have a thermal conductivity of 39 W/mK. The circuit layer is direct bonded to the dielectric layer. In some cases, this copper layer is bonded with an adhesive layer. While thin, the thermal, conductivity of the adhesive is very low; commonly less than 0.05 W/mK. The dielectric FR4 base substrate can have a thermal conductivity of 0.25 W/mK.

The FR4 base is commonly bonded using an adhesive interface to the aluminum substrate. These, adhesives can have very low thermal conductivity; commonly less than 0.05 W/mK. The thermal conductivity of aluminum is 175 W/mK and the thermal conductivity of copper is 355. W/mK. Alloys of aluminum and alloys of copper can raise or lower the thermal conductivity depending on the type and quantity of dopants.

An additional interface is involved when these MCPCBs are mounted onto a heat sink. This interface is often a mechanical contact when the MCPCB is bolted or glued to the heat sink. In the case of a mechanical fastener or bolt-on mounting, mismatched surface roughness of the heat sink and MCPCB create micro-sized air gaps between the boards. These air gaps are removed by the inclusion of thermal interface material such as a silicone-based grease compound. The thermal conductivity of air is 0.0275 W/mK, and the thermal conductivity of many thermal interface materials (TIMs*) can be up to 10 W/mK for very high performance materials. However, most TIMs have a thermal conductivity of less than 4 W/mK.

Summing up such a foregoing thermal stack includes 9 layers. Starting from the heat sink these layers are: heat sink, thermal grease or adhesive, aluminum backing on the MCPCB, adhesive layer, FR4 circuit board material, adhesive layer, copper circuit conductor, solder layer, and electrical component. Each of these 9 layers has an interface. Phonon propagation across the interlace of two dissimilar materials is often poor, resulting in a overall low thermal conductivity. The thermal conductivity of each individual material in a stack can be summed and reported as a thermal impedance. Thermal impedance is calculated using the equation

Θ=L/(κA)

where Θ is the thermal impedance in K/Watt,

L=the thermal path length (or thickness of material, layer) in m,

κ=the thermal conductivity of the material layer in W/mK, and

A=the cross sectional area through which the heat is transferred.

Low thermal impedance is desired to transfer more heat and reduce overall device temperature. Thermal impedance is calculated by summing the thickness, cross-sectional area and thermal conductivity of each individual layer in a stack of materials. The total thermal impedance should be less than 1.5 K/W to be considered a high performance thermal management substrate. Embodiments of the present invention decrease the total number of layers in the thermal stack and decrease the total thickness of each remaining layer to decrease the resultant thermal impedance. Embodiments of the present invention disclose materials and methods for providing a thermal management approach that has high heat dissipation properties.

### BRIEF DESCRIPTION OF THE DRAWINGS

FIG. 1 illustrates embodiments of the present invention.

FIG. 2 illustrates a flow diagram in accordance with embodiments of the present invention.

FIG. 3 illustrates a flow diagram in accordance with embodiments of the present invention.

### DETAILED DESCRIPTION

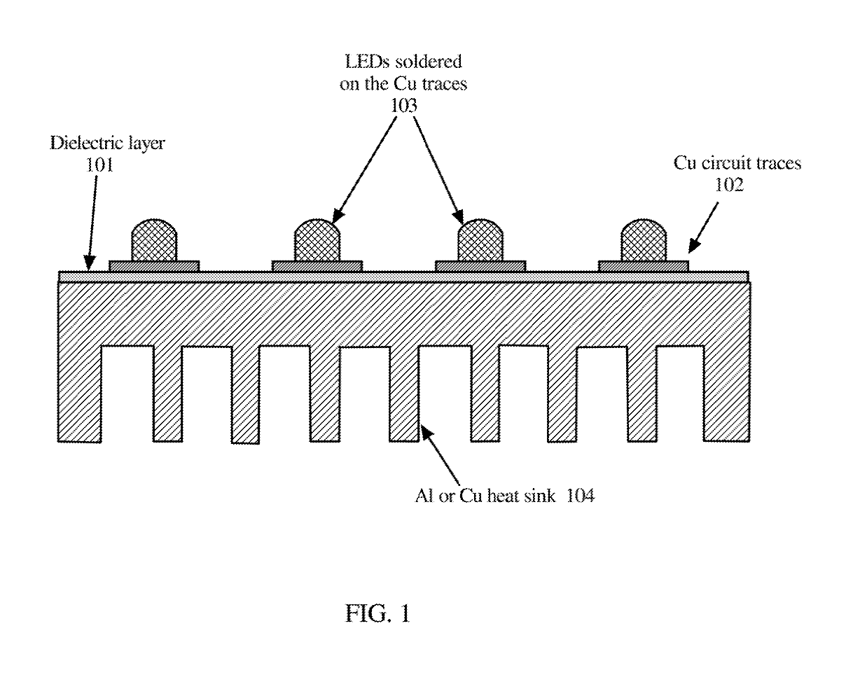

Referring to FIG. 1, embodiments of the present invention directly apply the dielectric layer 101 and Cu circuit traces 102 on the Al or Cu heat sink parts 104 so that one can eliminate the use of separately manufactured LED circuit boards. A process for making embodiments of the present invention may first start with a preparation of the surface of the heat sink part 104 such as polishing such a surface. The dielectric layer 101 is directly applied onto the surface of the heat sink part 104, such as in accordance with the various examples described herein. For example, the composition for making the dielectric layer may be made into a paste or ink and then printed as a paste or ink, or applied with some other equivalent method for applying a paste or ink. Or, a lamination process may be utilized, as further described herein. The electrical circuit traces are then applied (e.g., printed as an ink or paste, lithographically patterned) onto the dielectric layer 101 in the required pattern for whatever circuitry is to be applied. That circuitry (e.g., circuit elements) is then attached to the electrical traces as needed for the particular application. As an example, power LEDs may be soldered, to the circuit traces, though the approach of embodiments of the present invention is not limited, to fabrication of electronic circuits for LEDs.

This provides at least the following advantages:

(1) Reduces the extra layers from heat sources (e.g., LEDs) to heat sink and then to environment, benefitting the heat dissipation.

(2) Reduces the cost by eliminating the use of LED circuit boards.

(3) Simplifies the manufacturing process.

(4) The dielectric layer and Cu traces on the heat, sink parts can be made with any printing or lamination process suitable for applying such materials. They can also be made by screen printing, spray methods, etc.

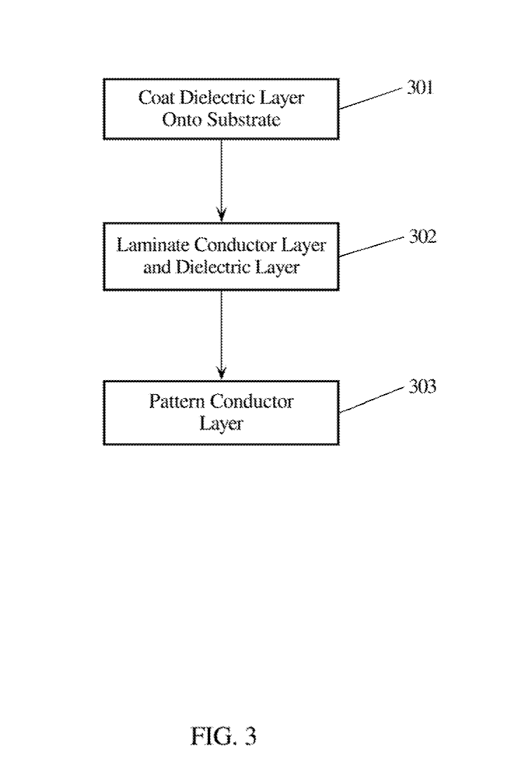

Referring to FIG. 3, embodiments of the present invention utilize a laminated dielectric and conductor configuration. In step 301, a planar metal substrate with high thermal conductivity is coated with a dielectric layer. The metal, may be either copper or aluminum. The dielectric layer may be a polyethylene-epoxy composite, which has a thermal conductivity of approximately 1-2 W/mK. The dielectric layer may have a thickness less than 10 μm and up to 50 μm. The dielectric serves as the adhesive layer between the conductor and the base substrate. The adhesion strength should be greater than 1 MPa, preferably greater than 2 MPa. The dielectric layer can be made as thin as possible for added benefits. A copper foil may be positioned on top of the metal substrate and dielectric layer. In step 302, using heat and pressure, the copper foil may be laminated to the metallic substrate using the dielectric layer as the adhesive. The lamination temperature is less than 200° C. The lamination, force is less than 5000 pounds of force. The dielectric layer serves as both the adhesive layer and the electrical isolation between the metallic substrate and the conductor layer. In step 303, the conductor layer may be patterned using standard lithographic techniques to create a desired circuit, pattern. The resulting structure can have electrical components soldered to the circuit pattern using solder reflow processes. The resulting structure has low thermal resistance between, the circuit conductor and the thermally conducting substrate. The thermal resistance is less than 1 K/W and preferably less than 0.7 K/W.

Referring to FIG. 3, embodiments of the present invention utilize a laminated dielectric and conductor on a graphitic substrate (e.g., CarbAl) configuration., in step 301, a planar graphitic substrate with high thermal conductivity is coated with a dielectric layer. The graphitic substrate has a thermal conductivity exceeding 300 W/mK. The dielectric layer may be a polyethylene-epoxy composite. The dielectric layer has a thermal conductivity of 1-2 W/mK. The dielectric layer may have a thickness less than 10 μm and up to 50 μm. The thickness depends on the surface roughness specification of the substrate. The dielectric layer should have a thickness greater than the surface roughness of the substrate. The dielectric layer may be made as thin as possible. A copper foil is positioned on top of the graphitic substrate and dielectric layer. In step 302, using heat and pressure the copper foil is laminated to the graphitic substrate using the dielectric layer as the adhesive. The lamination

temperature is less than 200° C. The lamination force is less than 3000 pounds of force. The dielectric layer serves as both the adhesive layer and the electrical isolation between the graphitic substrate and the conductor layer. In step 303, the conductor layer is patterned using standard lithographic techniques to create a desired circuit pattern. The resulting structure can have electrical components soldered to the circuit pattern using solder reflow processes. The resulting structure has low thermal resistance between the circuit conductor and the thermally conducting substrate.

Referring to FIG. 3, embodiments of the present invention laminate on a heat sink. In step 301, a metallic heat sink with one planar side and with high thermal conductivity is coaled with a dielectric layer. The metal may be either copper or aluminum. The dielectric layer may be a polyethylene-epoxy composite. The dielectric layer has a thermal conductivity of 1-2 W/mK. The dielectric layer can have a thickness less than 10 μm and up to 50 μm. The dielectric layer may be made as thin as possible. A copper foil is positioned on top of the metal heat sink and dielectric layer. In step 302, using heat and pressure, the copper foil is laminated to the metallic heat sink using the dielectric layer as the adhesive. The lamination temperature Is less than 200° C. The lamination force is less than 5000 pounds of force. The dielectric layer serves as both the adhesive layer and the electrical isolation between the metallic heat sink and the conductor layer. In step 303, the conductor layer is patterned using standard lithographic techniques to create a desired circuit pattern. The resulting structure can have electrical components soldered to the circuit pattern using solder reflow processes. The resulting structure has low thermal resistance between the circuit conductor and the thermally conducting heat sink.

Referring to FIG. 3, embodiments of the present invention laminate on a graphitic substrate (e.g., CarbAl) heat sink. In step 301, a graphitic heat sink with one planar side with high thermal conductivity is coated with a dielectric layer. The graphitic heat sink has a thermal conductivity exceeding 300 W/mK. The dielectric layer may be a polyethylene-epoxy composite. The dielectric layer has a thermal conductivity of 1-2 W/mK. The dielectric layer may have a thickness less than 10 μm and up to 50 μm. The thickness depends on the surface roughness specification of the heat sink. The dielectric layer should have a thickness greater than the surface roughness of the heat sink. The dielectric layer may be made as thin as possible. A copper foil is positioned on top of the graphitic heat sink and dielectric layer. In step 302, using heat and pressure, the copper foil is laminated to the graphitic heat sink using the dielectric layer as the adhesive. The lamination temperature is less than 200 C. The lamination force is less than 3000 pounds of force. The dielectric layer serves as both the adhesive layer and the electrical isolation between the graphitic heat sink and the conductor layer. In step 303, the conductor layer is patterned using standard lithographic techniques to create a desired circuit pattern. The resulting structure can have electrical components soldered to the circuit pattern using solder reflow processes. The resulting structure has low thermal resistance between the circuit conductor and the thermally conducting heat sink. The heat sink structure has superior radiation loss due to the carbon thermal conductor. The carbon emissivity is greater than an aluminum or copper heat, sink structure.

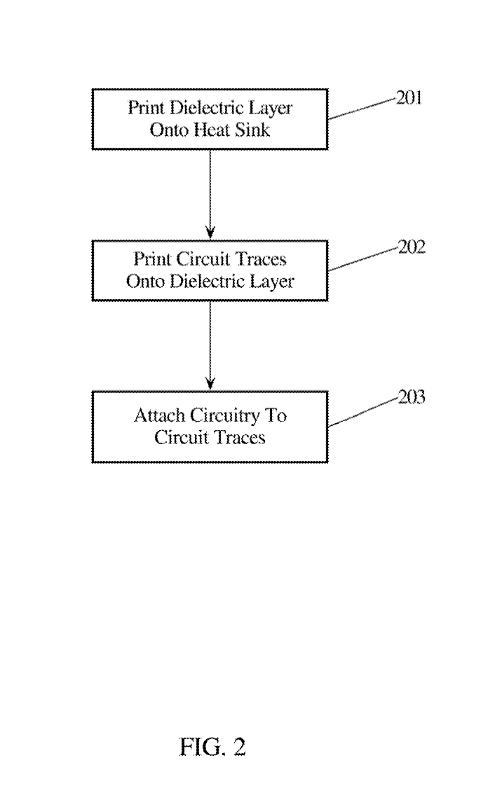

Referring to FIG. 2, embodiments of the present invention utilize a configuration with a printed dielectric and printed conductor. In step 201, a metallic substrate with high thermal conductivity is coated with a dielectric layer. The substrate may be aluminum, copper, or other metal with a thermal conductivity exceeding 180 W/mK. The substrate may be planar or have the shape of a heat sink. The dielectric layer may be a liquid polymer with ceramic particle filling. The liquid polymer may be a high temperature polymer, such as polyimide. The polymer has a thermal stability up to 450° C. The liquid polymer may be a high temperature polymer such as a silsesquioxane with a temperature stability up to 600° C. The ceramic particles filling the high temperature polymer may be made from SiO₂, BN, AlN, TiN, Al₂O₃, or other particles with high thermal conductivity and are considered electrical insulators. The mass loading of the ceramic particles in the polymer may range from 51-90%. The higher the loading of the ceramic particles in the polymeric matrix, the higher the thermal conductivity. The polymer dielectric may have a viscosity of 20,000-90,000 cP. The polymeric matrix loaded with ceramic particles may have a thermal conductivity of 4-20 W/mK.

In step 201, the polymer dielectric coating is printed onto the metallic substrate using screen printing, flexographic printing, dispenser, or other print, method. The dielectric coating may be blanket coated over the entire substrate or in a specific pattern, relative to a circuit structure. The dielectric coating may have a thickness of 5-100 μm. A thin polymer dielectric layer will have lower thermal resistance. In some cases, the ceramic particles will act as spacers to prevent electrical shorts between the thermally conductive substrate and the circuit layer. After printing, the polymer dielectric may be dried and then cured at a temperature less than 200° C.

In step 202, copper circuit pattern is printed onto the polymer dielectric layer (e.g., using a copper particle based ink or paste). The ink or paste may contain a solvent, dispersant, viscosity modifier, and metallic particles, examples of which are disclosed in U.S. Published Patent Application Nos. 2008/0286488, 2009/0242854, and 2010/0000762, which are all hereby incorporated by reference herein. The copper particles may range from 10 nm to 2 μm in diameter. The smaller particles may be used primarily in an ink with low viscosity (10-1000 cP). The ink may be printed using an inkjet printer to deposit a specified circuit pattern. The larger particles (e.g., >100 nm) may be primarily used in a paste with a higher viscosity (e.g., >1000 cP). The resulting paste may be printed using a screen printer, flexographic, gravure, or dispenser. A typical printed thickness may be approximately 1-5 urn with a maximum of approximately 10 μm. After printing and drying, the ink or paste may be cured using a photosintering technique. The ink may be further electroplated with copper to increase its thickness up to 90 microns or 3 oz. copper equivalent.

In step 203, the resulting structure may have electrical components soldered to the copper circuit layer using solder reflow processes. The resulting structure has low thermal-resistance between the circuit conductor and the thermally conducting heat sink. The heat sink structure has superior radiation loss due to the carbon thermal conductor. The carbon emissivity is greater than an aluminum or copper heat sink structure.

Referring to FIG. 2, embodiments of the present invention may implement a configuration of a printed dielectric, printed circuit, and a graphitic substrate (e.g., CarbAl) substrate. In step 201, graphitic carbon substrate with high thermal conductivity is coated with a dielectric layer. The substrate may have a thermal conductivity exceeding 300 W/mK. The substrate may be planar or have the shape of a heat sink. The dielectric layer may be a liquid polymer with ceramic particle filling. The liquid polymer may be a high temperature polymer, such as polyimide. The polymer has a thermal stability up to 450° C. The liquid polymer may be a high temperature polymer, such as a silsesquioxane with a temperature stability up to 600° C. The ceramic particles filling the high temperature polymer may be made from SiO₂, BN, AlN, TiN, Al₂O₃, or other particles with high thermal conductivity and are considered electrical insulators. The mass loading of the ceramic particles in the polymer may range from -approximately 51-90%. The higher the loading of the ceramic particles in the polymeric matrix, the higher the thermal conductivity. The polymer dielectric may have a viscosity of 20,000-90,000 cP. The polymeric matrix loaded with ceramic particles may have a thermal conductivity of 4-20 W/mK.

In step 201, the polymer dielectric coating may be printed onto the metallic substrate using screen printing, flexographic printing, a dispenser, or other print method. The dielectric coating may be blanket coated over the entire substrate or in a specific pattern relative to a circuit structure. After printing, the polymer dielectric may be dried and cured at a temperature less than 200° C. The dielectric coating may have a final thickness of approximately 5-100 μm. A thin polymer dielectric layer will have lower thermal resistance, hi some cases, the ceramic particles can act as spacers to prevent electrical, shorts between, the thermally conductive substrate and the circuit layer. The thermal conductivity of the cured polymer increases with the final density of the polymer. A density greater than 2 g/cm² will provide sufficient thermal conductivity to meet the thermal impedance requirements to exceed 4 W/mK.

In step 202, a circuit pattern (e.g., copper) is printed onto the polymer dielectric layer (e.g., using a copper particle based ink or paste). The ink or paste may contain a solvent, dispersant, viscosity modifier, and metallic particles, examples of which are disclosed in U.S. Published Patent Application Nos. 2008/0286488, 2009/0242854, and 2010/0000762, which are all hereby incorporated by reference herein. The copper particles may range from 10 nm to 2 μm in diameter. The smaller particles may be used primarily in an ink with low viscosity (e.g., 10-1000 cP). The ink may be printed using an Inkjet printer to deposit a specified circuit pattern. The larger particles (e.g., >100 nm) may be primarily used in a paste with a higher viscosity (e.g., >1000 cP). The resulting paste may be printed using a screen printer, flexographic, gravure, or dispenser. A typical printed thickness is approximately 1-5 μm with a maximum of approximately 10 μm. After printing and drying, the ink or paste may be cured using a photosintering technique. The ink may be further electroplated with copper to increase its thickness up to 90 microns or 3 oz. copper equivalent.

In step 203, the resulting structure may have electrical components soldered to the circuit layer using solder reflow processes. The resulting structure has low thermal resistance between the circuit conductor and the thermally conducting heat sink. The heat sink structure has superior radiation loss due to the carbon thermal conductor. The carbon emissivity is greater than an aluminum or copper heat sink structure.

Referring to FIG. 3, embodiments of the present invention implement a configuration of a printed dielectric and a laminated circuit. In step 301, a metallic substrate with high thermal conductivity is coated with a dielectric layer. The substrate may be aluminum, copper, or other metal with a thermal conductivity exceeding 180 W/mK. The substrate may be planar or have the shape of a heat sink. The dielectric layer may be a liquid polymer with ceramic particle filling. The liquid polymer may be a high temperature polymer, such as polyimide. The polymer has a thermal stability up to 450° C. The liquid polymer may be a high temperature polymer, such as a silsesquioxane with a temperature stability up to 600° C. The ceramic particles filling the high temperature polymer may be made from SiO₂, BN, AlN, TiN, Al₂O₃, or other particles with high thermal conductivity and are considered electrical insulators. The mass loading of the ceramic particles in the polymer may range from approximately 51-90%. The higher the loading of the ceramic particles in the polymeric matrix, the higher the thermal conductivity. The polymer dielectric may have a viscosity of approximately 20,000-90,000 cP. The polymeric matrix loaded with ceramic particles may have a thermal conductivity of 4-20 W/mK.

In step 301, the polymer dielectric coating is printed onto the metallic substrate (e.g., using screen printing, flexographic printing, dispenser or other print method). The dielectric coating may be blanket coated over the entire substrate or in a specific pattern relative to a circuit structure. The dielectric coating may have a final thickness of approximately 5-100 μm. A thin polymer dielectric layer will have lower thermal resistance, in some eases, the ceramic particles may act as spacers to prevent electrical shorts between the thermally conductive substrate and the circuit layer. The polymer may be soft-baked at a temperature less than 100° C. to prevent How and maintain its volume and location on the substrate.

A copper foil is positioned on top of the graphitic heat sink and dielectric layer. In step 302, using heat and pressure, the copper foil is laminated to the graphitic heat sink using the dielectric layer as the adhesive. The lamination temperature is less than 200° C. The lamination force is less than 3000 pounds of force. The dielectric layer serves as both the adhesive layer and the electrical isolation between the graphitic heat sink and the copper conductor layer. In step 303, the conductor layer may be patterned using standard lithographic techniques to create a desired circuit pattern. The resulting structure may have electrical components soldered to the copper circuit layer using solder reflow processes. The resulting structure has low thermal resistance between the circuit conductor and the thermally conducting heat sink.

Referring to FIG, 3, embodiments of the present invention implement a configuration printed dielectric, a laminated circuit, and a graphitic substrate (e.g., CarbAl) substrate. In step 301, a graphitic carbon substrate with high thermal conductivity is coated with a dielectric layer. The substrate may have a thermal conductivity exceeding 300 W/mK. The substrate may be planar or have the shape of a heat sink. The dielectric layer may be a liquid polymer with ceramic particle filling. The liquid polymer may be a high temperature polymer, such as polyimide. The polymer has a thermal stability up to 450° C. The liquid polymer may be a high temperature polymer, such as a silsesquioxane with a temperature stability up to 600° C. The ceramic particles filling the high temperature polymer may be made from SiO₂, BN, AlN, TiN, Al₂O₃, or other particles with high thermal conductivity and are considered electrical insulators. The mass loading of the ceramic particles in the polymer may range from approximately 51-90%. The higher the loading of the ceramic panicles in the polymeric matrix, the higher the thermal conductivity. The polymer dielectric has a viscosity of approximately 20,000-90,000 cP. The polymeric matrix loaded with ceramic particles may have a thermal conductivity of 4-20 approximately W/mK.

In step 301, the polymer dielectric coating is printed onto the metallic substrate (e.g., using screen printing, flexographic printing, dispenser, or other print method). The dielectric coating may be blanket coated over the entire substrate or in a specific pattern relative to a circuit structure. The dielectric coating may have a final thickness of approximately 5-100 μm. A thin polymer dielectric layer will have lower thermal resistance, in some cases, the ceramic particles may act as spacers to prevent electrical shorts between the thermally conductive substrate and the circuit layer. The polymer may be soft-baked at a temperature less than 100° C. to prevent flow and maintain its volume and location on the substrate.

A copper foil is positioned on top of the graphitic heat sink and dielectric layer. In step 302, using heat and pressure, the copper foil is laminated to the graphitic heat sink using the dielectric layer as the adhesive. The lamination temperature is less than 200° C. The lamination force is less than 3000 pounds of force. The dielectric layer serves as both the adhesive layer and the electrical isolation between the graphitic heat, sink and the conductor layer. In step 303, the conductor layer may be patterned using standard lithographic techniques to deposit a specified circuit pattern. The resulting structure may have electrical components soldered to the copper circuit layer using solder reflow processes. The resulting structure has low thermal resistance between the circuit conductor and the thermally conducting heat sink. The heat sink structure has superior radiation loss due to the carbon thermal conductor. The carbon emissivity is greater than an aluminum or copper heat sink structure.

Embodiments of the present invention may utilize an epoxy or polyimide type of material for use as the dielectric layer 101. Polyimide material is lightweight, flexible, and resistant to heat and chemicals- Therefore, it can he used in the electronics industry as flexible substrates or insulating layers. But, polyimide material has a very low thermal conductivity (approximately 0.3 W/m-K) that limits its application for high power electronics due to thermal issues.

Embodiments of the present invention use highly thermal conductive ceramic powders (e.g., AlN (aluminum nitride) powders) to add into a polyimide to produce dielectric polyimide/AlN composite films, which have a thermal conductivity over ten times greater than pure polyimide film.

Fabrication of the polyimide/AlN composite films may comprise preparing a polyimide/AlN ink or paste, and making polyimide/AlN films from the polyimide/AlN ink or paste. A fabrication procedure may comprise:
(1) Dissolving a polyimide resin into a solvent such as, but not limited to, 1-Methyl-2-prrodilidone, to make a polyimide solution, wherein the polyimide weight percentage may range from approximately 10-50%.
(2) Adding AlN powders into the polyimide solution with a specified weight ratio (e.g., approximately 40-80%). In certain embodiments of the present invention, this weight ratio for the ceramic powders is equal or greater than approximately 60 wt %, which then provides a dielectric layer having a thermal, conductivity greater than or equal to approximately 4 W/m-K.
(3) Mixing the AlN powders with the polyimide solution (e.g., with ultrasonic or SpeedMixture tools, etc.) to obtain a polyimide/AlN paste.
(4) Coating the polyimide/AlN paste on Cu (copper) foils with, but not limited to, a screen printing method.
(5) Drying the printed paste layer ((e.g., at approximately 100-120° C. for 30-60 minutes and then approximately 250° C. for 60 minutes).

(6) Dissolving the Cu foil in an etching solution (e.g., CuSO₄/H₂SO₄ or FeCl₃/HCl at room temperature).

(7) Rinsing with deionized water.

(8) Baking (e.g., at approximately 80-120° C. for 30-60 minutes) to obtain, a dried polyimide/AlN free-standing composite film, which can then be laminated onto the heat sink part.

Alternatively, the polyimide/AlN paste may be directly applied, such as with a printing technique onto the heat sink part.

Embodiments of the present invention manufacture polyimide/ceramic composite films that are electrically insulating and have improved thermal, performances compared with pure polyimide films. The added ceramic powders are not limited to the AlN powders, hut may also be BN, SiC, Al₂O₃, or diamond powders, or others, or a mixture of any of them. The ceramic powder size may range from approximately 10 nm to 100 μm. The ceramic powders added into polyimide may be a mixture of small powders and large powders. The volume fraction of ceramic powders In the composite films may range .from approximately 20-90%. The polyimide materials may be thermal cured or photo-cured. Fabricated polyimide/ceramic may be mounted on metal or graphitic carbon, substrates as the dielectric layers, or directly deposited polyimide/ceramic dielectric layers from polyimide/ceramic solutions on metal or graphitic carbon substrates by printing, spray, or spin coating methods, such as discussed above with respect to FIGS. 1 and 2.

1. A method comprising:
printing a dielectric layer onto a heat sink part; and
printing conductive traces onto the dielectric layer.

2. The method as recited in claim 1, further comprising electrically coupling electronic circuit elements to the conductive traces.

3. The method as recited in claim 2, wherein the electronic circuit elements comprise light emitting diodes.

4. The method as recited in claim 1, wherein the heat sink part has a thermal conductivity greater than 180 W/mK.

5. The method as recited in claim 1, wherein the heat sink part is selected from the group consisting of aluminum, copper, carbon, or any combinations of the foregoing.

6. The method as recited in claim 2, wherein the electronic circuit elements are soldered to the conductive traces.

7. The method as recited in claim 1, wherein a thermal conductivity of the dielectric layer is greater than 1 W/mK.

8. The method as recited in claim 1, wherein the printed dielectric layer is a composite film comprising a polymer and ceramic particles embedded within the polymer.

9. The method as recited in claim 8, wherein the ceramic is selected from the group consisting of AlN, BN, SiC, Al₂O₃, diamond, and any combination of the foregoing.

10. The method as recited in claim 8, wherein loading of the ceramic particles in the composite film creates a film density greater than 2 g/cm³.

11. A method comprising:
coating a dielectric layer onto a substrate;
laminating the dielectric layer between the substrate and a conductor layer using a heat and pressure lamination process; and
patterning the conductor layer with specified conductive traces.

12. The method as recited in claim 11, further comprising electrically coupling electronic circuit elements to the conductive traces.

13. The method as recited in claim 12, wherein the electronic circuit elements comprise light emitting diodes.

14. The method as recited in claim 11, wherein the substrate comprises a heat sink that has a thermal conductivity greater than 180 W/mK.

15. The method as recited in claim 14, wherein the heat sink is graphitic.

16. The method as recited in claim 11, wherein the dielectric layer is a composite film comprising a polymer and a ceramic.

17. The method as recited in claim 16, wherein the ceramic is selected from the group consisting of AlN, BN, SiC, Al₂O₃, diamond, and any combination of the foregoing.

18. The method as recited in claim 16, wherein loading of the ceramic in the composite film creates a film density greater than 2 g/cm².

19-30. (canceled)

31. The method as recited in claim 9, wherein the polymer is silsesquioxane.

32. The method as recited in claim 8, wherein a mass loading of the ceramic particles in the composite film is in a range of 51%-90%.

33. The method as recited in claim 8, wherein the ceramic particles in the printed printed dielectric layer act as spacers preventing electrical shorts between the heat sink part and conductive traces.

34. The method as recited in claim 1, wherein the conductive traces are printed as a copper particle based ink or paste, the method further comprising photosintering the printed copper particle based ink or paste.

35. The method as recited in claim 16, wherein the conductor layer is a copper foil that is adhered to the substrate by the lamination of the composite film comprising the polymer and the ceramic.

36. The method as recited in claim 35, wherein an adhesion strength between the copper foil and the substrate is greater than 1 MPa.

37. The method as recited in claim 35, wherein a force of the lamination of the composite film to the substrate is less than 5000 pounds.

38. The method as recited in claim 14, wherein a thermal resistance between the conductor layer and the heat sink is less than 1 K/W.

39. The method as recited in claim 16, wherein the composite film comprises the polymer in a liquid form with the ceramic embedded therein as ceramic particles.

40. The method as recited in claim 39, wherein the ceramic particles in the printed printed dielectric layer act as spacers preventing electrical shorts between the heat sink part and conductive traces.

41. A method comprising:
coating a dielectric layer onto a copper foil, wherein the dielectric layer is a composite film comprising a polyimide and aluminum nitride particles;
drying the composite film coated onto the copper foil; and
laminating the copper foil to a heat sink part using a heat and pressure lamination process that results in the composite film adhering the copper foil to the heat sink part.

42. The method as recited in claim 41, further comprising:
patterning the copper foil with specified conductive traces; and
soldering electronic circuit elements to the conductive traces.
